(19) United States
(12) Patent Application Publication
(10) Pub. No.: US 2021/0385967 A1
(43) Pub. Date: Dec. 9, 2021

(54) IN-VEHICLE COMPUTER AND VEHICLE WITH THE IN-VEHICLE COMPUTER

(71) Applicants: Inventec (Pudong) Technology Corp., Shanghai (CN); Inventec Corporation, Taipei (TW)

(72) Inventors: Chi-Cheng Hsiao, Taipei (TW); Ling Chiang, Taipei (TW)

(21) Appl. No.: 16/903,339

(22) Filed: Jun. 16, 2020

(30) Foreign Application Priority Data
Jun. 9, 2020 (CN) 202010526183.6

(51) Int. Cl. H05K 7/20; G06F 1/18; G06F 1/20; B60R 16/02

(52) U.S. Cl. CPC H05K 7/20172; B60R 16/02; G06F 1/20; G06F 1/182

(57) ABSTRACT

An in-vehicle computer includes a computer casing, a filtering structure, and a fan. The computer casing has a casing accommodating space and a vent opening communicating with the casing accommodating space. The filtering structure is detachably disposed at the vent opening. The fan is disposed in the casing accommodating space and spaced from the vent opening. A suction port of the fan is toward the vent opening. The fan generates an airflow, for dissipating heat from an electronic component in the casing accommodating space. By the filtering effect of the filtering structure, the particle amount in the airflow can be reduced. A vehicle includes a vehicle cage and the in-vehicle computer, disposed in the vehicle cage. The vent opening communicates with the cockpit space of the vehicle cage, so that the fan can draw lower-temperature air for enhancing the heat dissipation efficiency.

### BACKGROUND OF THE INVENTION

### 1. Field of the Invention

The present invention relates to an in-vehicle computer, and more particularly to an in-vehicle computer having a filtering structure and a vehicle having the in-vehicle computer.

### 2. Description of the Prior Art

As the breadth and depth of vehicle electronic control systems increase in vehicle control, the system complexity and device volume of the vehicle electronic control systems also increase, and the demand for operational stability of vehicle electronic control systems also increases. At present, in-vehicle computers are usually simply fixed on the vehicle cage, such as in the rear trunk or other compartments thereof. However, the interior of the vehicle is not as good as the interior of a house, and the air quality inside the vehicle is poor and dusty, which is not conducive to heat dissipation of the in-vehicle computer. Furthermore, the space of the rear trunk is relatively closed and poorly ventilated, which also is not conducive to heat dissipation of the in-vehicle computer. When the vehicle is parked outdoors and exposed to the sun, the temperature inside the vehicle rises rapidly. After the vehicle is started, even if the air condition is turned on, the temperature in the rear trunk still cannot be reduced, which is not conducive to heat dissipation of the in-vehicle computer. Furthermore, at this time, the temperature may seriously affect the operation of the in-vehicle computer, and even affect the driving safety. Therefore, for increasingly complex in-vehicle computers, there is a need to improve the configuration of the heat dissipation of the in-vehicle computers.

### SUMMARY OF THE INVENTION

An objective of the invention is to provide an in-vehicle computer with a filtering structure. The filtering structure can reduce the amount of particles contained in the intake air, which is conducive to heat dissipation.

An in-vehicle computer according to the invention includes a computer casing, a filtering structure, an electronic component, and a fan. The computer casing has an accommodating space and a vent opening communicating with the accommodating space. The filtering structure is detachably disposed at the vent opening. The electronic component is disposed in the casing accommodating space. The fan is disposed in the casing accommodating space and spaced from the vent opening. The fan has a suction port and an exhaust port. The suction port is toward the vent opening. The fan generates an airflow for dissipating heat from the electronic component. Through the filtering effect of the filtering structure, the amount of particles contained in the airflow can be reduced, which is conducive to heat dissipation.

Another objective of the invention is to provide a vehicle, which includes an in-vehicle computer like the above. The in-vehicle computer communicates with a cockpit space of the vehicle so as to draw cooler air therefrom for enhancing the heat dissipation efficiency.

A vehicle computer according to the invention includes a vehicle cage and an in-vehicle computer. The vehicle cage has a cockpit space. The in-vehicle computer is disposed in the vehicle cage and includes a computer casing, a filtering structure, an electronic component, and a fan. The computer casing has a casing accommodating space and a vent opening communicating with the casing accommodating space. The filtering structure is detachably disposed at the vent opening. The electronic component is disposed in the casing accommodating space. The fan is disposed in the casing accommodating space and spaced from the vent opening. The fan has a suction port and an exhaust port. The suction port is toward the vent opening. The fan generates an airflow for dissipating heat from the electronic component. Through the filtering effect of the filtering structure, the amount of particles contained in the airflow can be reduced, which is conducive to heat dissipation. The casing accommodating space communicates with the cockpit space through the vent opening, so that the fan can draw cooler air from the cockpit space so as to enhance the heat dissipation efficiency.

Compared with the prior art, the in-vehicle computer and the vehicle with the in-vehicle computer according to the invention can use the filtering structure to reduce the amount of the particles contained in the airflow for heat dissipation, which solves the problem in the prior art that the air quality in the vehicle is poor, which is not conducive to heat dissipation. Furthermore, because of the communication of the in-vehicle computer with the cockpit space of the vehicle cage through the vent opening, the fan can draw cooler air for enhancing the heat dissipation efficiency, which solves the problem in the prior art that the current in-vehicle computer are limited by the location and not easy to dissipate heat.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a vehicle with an in-vehicle computer according to an embodiment.

FIG. 2 is a schematic diagram illustrating the in-vehicle computer in FIG. 1.

FIG. 3 is a partially exploded view of the in-vehicle computer in FIG. 2.

FIG. 4 is another partially exploded view of the in-vehicle computer in FIG. 2.

FIG. 5 is a schematic diagram illustrating a cross section of the in-vehicle computer along the line X-X in FIG. 2.

FIG. 6 is a schematic diagram illustrating the interior of the vehicle at a back seat in FIG. 1.

### DETAILED DESCRIPTION

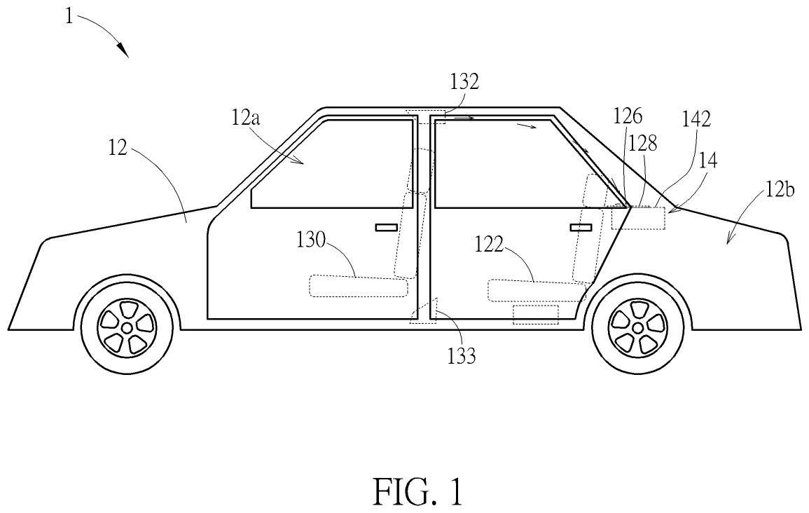

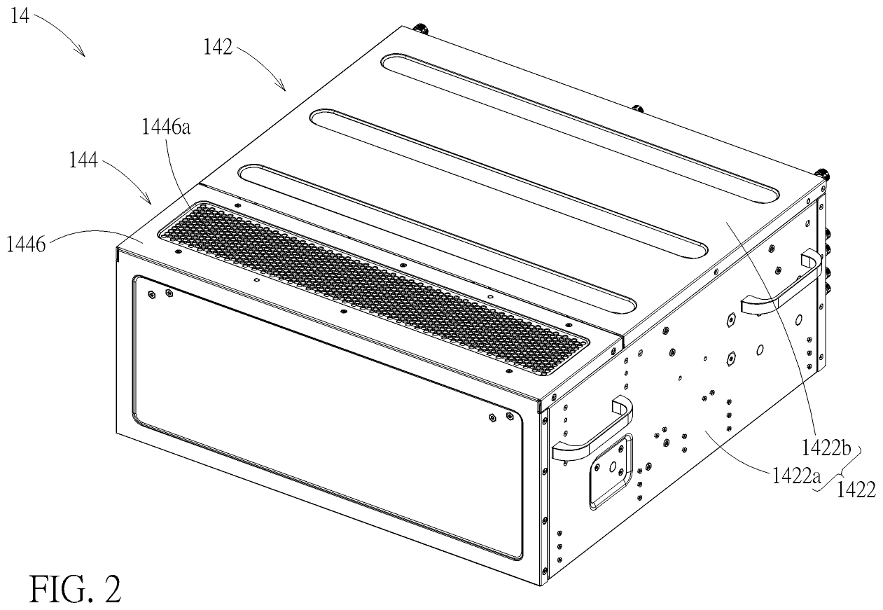

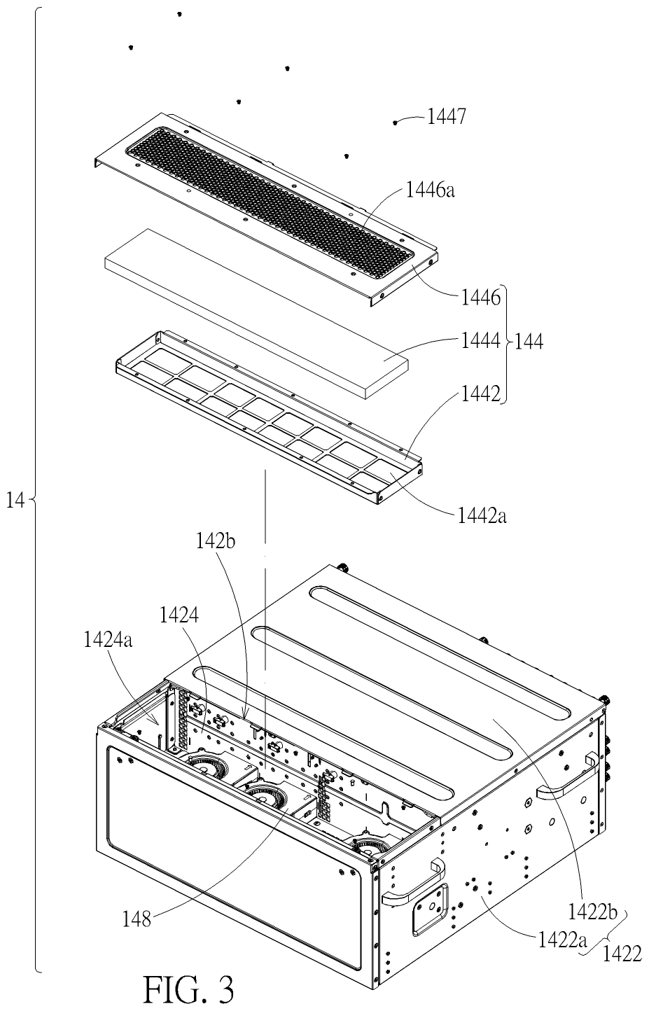

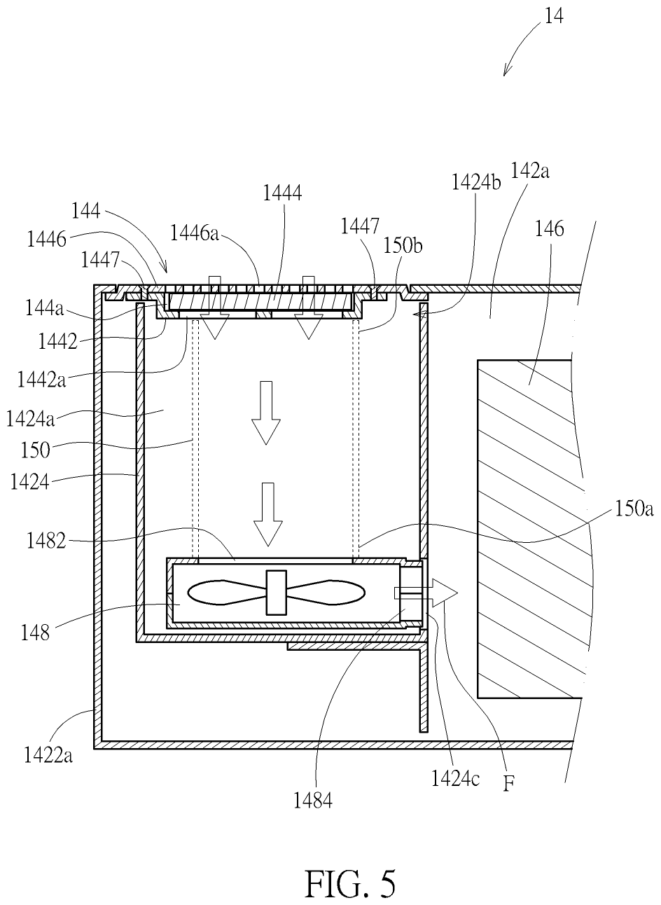

Please refer to FIG. 1 to FIG. 5. A vehicle 1 according to an embodiment includes a vehicle cage 12 and an in-vehicle computer 14 (of which the profile in FIG. 1 is shown in dashed lines) disposed in the vehicle cage 12. The in-vehicle computer 14 includes a computer casing 142, a filtering structure 144, an electronic component 146, and a fan 148. The computer casing 142 has a casing accommodating space 142a and a vent opening 142b communicating with the casing accommodating space 142a. The filtering structure 144 is detachably disposed in the vent opening 142b. The electronic component 146 (shown by a solid block for drawing simplification; in practice, the electronic component 146 can be but not limited to a system mainboard, a memory module, a hard drive disk, a power supply module, an expansion card, or other components that will produce heat during operation) is disposed in the casing accommodating space 142a. The fan 148 is disposed in the casing accommodating space 142a and spaced from the vent opening 142b. The fan 148 (e.g. but not limited to an axial fan, a centrifugal fan, or a blower) can generate an airflow F (indicated by hollow arrows in FIG. 5) for dissipating heat from the electronic component 146. The fan 148 has a suction port 1482 and an exhaust port 1484. The suction port 1482 is toward the vent opening 142b, so that the fan 148 can draw the air filtered by the filtering structure 144. Through the filtering effect of the filtering structure 144, the amount of particles contained in the air entering the computer casing 142 through the vent opening 142b can be reduced; the particles contained in the airflow F is therefore reduced.

Furthermore, in the embodiment, the computer casing 142 includes a main casing 1422, which forms the casing accommodating space 142a and the vent opening 142b. For more details, the main casing 1422 includes a base 1422a and a top cover 1422b. The top cover 1422b is detachably connected to the base 1422a to form the accommodating space 142a. The top cover 1422b (or an edge thereof) and the base 1422a (or edges of three side walls) together form the vent opening 142b; however, it is not limited thereto in practice. For example, the main casing 1422 is provided in other structural forms, e.g. in which the top cover 1422b is pivotally connected to the base 1422a. For another example, the top cover 1422b alone forms the vent opening 142b.

The filtering structure 144 is detachably connected to the main casing 1422 to seal the vent opening 142b. In the embodiment, the filtering structure 144 includes a bottom bracket 1442, a replaceable filtering material 1444, and an upper cover 1446. The upper cover 1446 and the bottom bracket 1442 are engaged with each other to form a filter accommodating space 144a. The replaceable filtering material 1444 is accommodated in the filter accommodating space 144a. Therein, the bottom bracket 1442 and the upper cover 1446 have hole structures 1442a and 1446a, so as to allow air to pass through. The replaceable filtering material 1444 can be realized by a common filter (e.g. including but not limited to one or more filter screens or cloths made of fibers or porous materials), which will not be described in addition. In the assembly of the filtering structure 144, the bottom bracket 1442 that carries the replaceable filtering material 1444 is joined to the upper cover 1446 from below the upper cover 1446 (e.g. by screws 1447), so as to form the filtering structure 144. Then, the upper cover 1446 can be assembled to the main casing 1422 for sealing the vent opening 142b; for example, the upper cover 1446 spans the side walls of the base 1422a and abuts against the top cover 1422b, and is fixed by screws. In practice, the filtering structure 144 can be structurally modified so that the bottom bracket 1442 spans the side walls of the base 1422a and abuts against the top cover 1422b so as to seal the vent opening 142b. Therein, the upper cover 1446 is only engaged to the bottom bracket 1442 for forming the filter accommodating space 144a for accommodating the replaceable filtering material 1444.

Furthermore, in the embodiment, the vent opening 142b is realized by a single hole structure. However, the vent opening 142b also can be realized by a grid structure; e.g. the portion of the top cover 1422b opposite to the fan 148 forms a grid structure as the vent opening 142b. For example, the grid structure is also taken as the bottom bracket 1442 of the filtering structure 144. The upper cover 1446 is connected to the grid structure to form the filter accommodating space for accommodating the replaceable filtering material 1444. Therein, the bottom bracket 1442 can be omitted. For another example, the grid structure is also taken as the upper cover 1446 of the filtering structure 144. The bottom bracket 1442 is connected to the grid structure to form the filter accommodating space for accommodating the replaceable filtering material 1444. Therein, the upper cover 1446 can be omitted. In addition, in the embodiment, the filtering structure 144 adopts a separable structure, so the bottom bracket 1442 and the upper cover 1446 can be separated for replacing the replaceable filtering material 1444; however, it is not limited thereto in practice. For example, the filtering structure 144 is provided by a single component (e.g. of which the outer casing cannot be disassembled in a recoverable manner). When the filtering function is insufficient, the entire filtering structure 144 needs to be replaced directly.

In the embodiment, the computer casing 142 also includes a fan cage 1424 for carrying the fan 148 to form a detachable fan module (including the fan cage 1424 and the fan 148), which is convenient to install or uninstall. The fan cage 1424 is disposed in the casing accommodating space 142a corresponding to the vent opening 142b. The fan cage 1424 has a fan accommodating space 1424a, a top opening 1424b, and a side through hole 1424c. The top opening 1424b is aligned with the vent opening 142b. The fan 148 is disposed in the fan accommodating space 1424a and fixed to the fan cage 1424. The suction port 1482 is toward the top opening 1424b. The exhaust port 1484 is connected to the side through hole 1424c toward the electronic component 146. The airflow F generated by the fan 148 can pass through the side through hole 1424c to flow toward the electronic component 146 for dissipating heat from the electronic component 146. In practice, a guiding structure can be connected to the side through hole 1424c to guide the airflow F to the electronic component 146 (e.g. for a case that the electronic component 146 does not face the side through hole 1424c or there is interference by other structure).

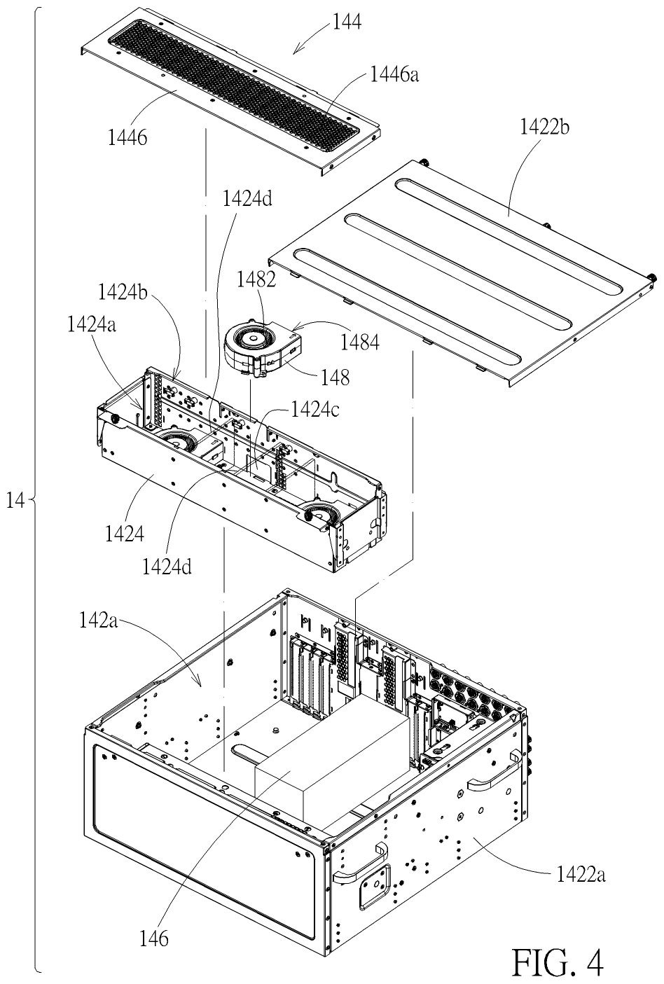

Furthermore, in practice, the in-vehicle computer 14 can further include a tubular structure 150 (of which the profile is shown in dashed lines in FIG. 5) disposed in the casing accommodating space 142a. Therein, an end of the tubular structure 150 is close to the suction port 1482 (e.g. connected to the suction port 1482); another end of the tubular structure 150 is close to the filtering structure 144 (e.g. abutting against the bottom bracket 1442 of the filtering structure 144). Thereby, the fan 148 can directly draw the air filtered by the filtering structure 144. In practice, the suction port 1482 of the fan 148 can structurally extend upward to form the tubular structure 150. In addition, in the embodiment, the in-vehicle computer 14 includes a plurality of the fans 148 in fact. The fan cage 1424 can include a plurality of partition plates 1424d (shown in dashed lines in FIG. 4) for partitioning the fan accommodating space 1424a into several subspaces for accommodating the fans 148 respectively. Each fan 148 in the corresponding subspace can draw the air filtered by the filtering structure 144. The partition plates 1424d can reduce the interference between the fans 148 when the fans 148 are in operation, which is also conducive to the efficiency of the fan 148 drawing the exterior air (filtered by the filtering structure 144).

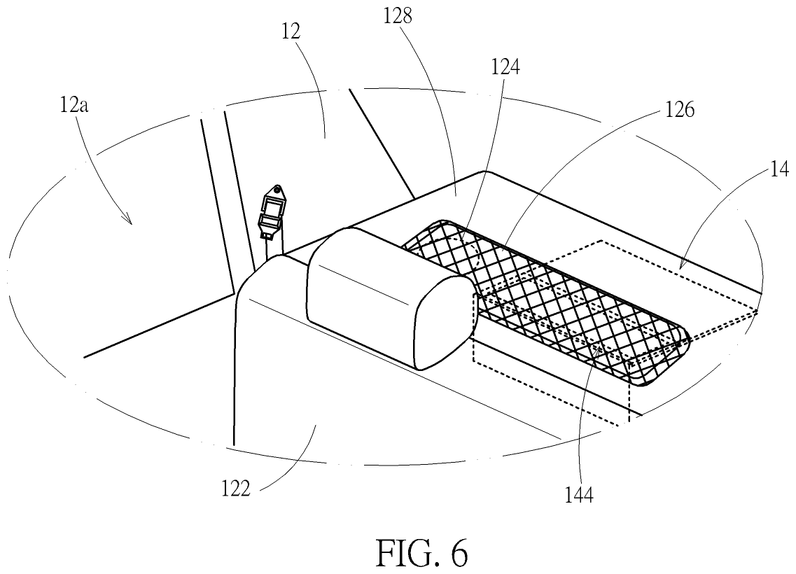

Please refer back to FIG. 1. In the embodiment, the vehicle cage 12 has a cockpit space 12a (including space for a driver and passengers to ride and move). The vent opening 142b of the computer casing 142 communicates with the cockpit space 12a. Thereby, the fan 148 can draw the air of lower temperature from the cockpit space 12a, so as to obtain a better heat dissipation effect. Please also refer to FIG. 6. In the embodiment, the vehicle cage 12 includes a back seat 122 disposed in the cockpit space 12a, a speaker 124 located behind the back seat 122 (or the head rest thereof), and a speaker mesh cover 126. The in-vehicle computer 14 is disposed in the rear trunk 12b close to the back seat 122 (which may be regarded as being disposed between the rear trunk 12b and the back seat 122), for example by fixing two sides of the computer casing 142 to a structural frame of the vehicle cage 12. The speaker 124 is usually fixed on a structural plate or a decorative plate 128. The speaker mesh cover 126 is exposed from the cockpit space 12a (and also can be fixed on the decorative plate 128) and simultaneously covers the speaker 124 and the filtering structure 144 (of the in-vehicle computer 14), giving consideration to both appearance and beauty. Therein, in FIG. 6, the profiles of the speaker 124 and the filtering structure 144 hidden by the speaker mesh cover 126 are shown in dashed lines, and the profile of the computer casing 142 is also shown in dashed lines.

Furthermore, in general, the speaker mesh cover 126 is located at a prominent place in the cockpit space 12a (e.g. the place behind the head rest of the back seat 122 in the embodiment). The air circulates. Thereby, when the air condition of the vehicle 1 is turned on, the fan 148 can effectively draw cool air through the vent opening 142b for enhancing the heat dissipation efficiency. Furthermore, in some car models, an air outlet 132 (indicated by a block in dashed lines in FIG. 1) is disposed at the upper middle of the cockpit space 12a (substantially between the front seat 130 and the back seat 122). The cool air from the air outlet 132 can effectively blows toward the speaker mesh cover 126 (of which the flowing path is indicated by arrows in FIG. 1), which helps the fan 148 to effectively draw the cool air through the vent opening 142b. In addition, in practice, the filtering structure 144 can be exposed from the decorative plate 128 independently from the speaker mesh cover 126. For example, the surface of the upper cover 1446 of the filtering structure 144 and the surface of the decorative plate 128 are substantially coplanar, also giving consideration to both appearance and beauty.

In addition, in the embodiment, although the in-vehicle computer 14 is not directly disposed in the cockpit space 12a, the in-vehicle computer 14 still can draw the cool air from the cockpit space 12a through the communication of the vent opening 142b with the cockpit space 12a. In practice, the in-vehicle computer 14 also can be disposed in the cockpit space 12a (e.g. under the seat which is indicated by a block in dashed lines under the back seat 122 in FIG. 1); therein, the ambient temperature of the location of the in-vehicle computer 14 is still lower than the rear trunk 12b, which is still conducive to the heat dissipation efficiency of the in-vehicle computer 14. Furthermore, in some car models, an air outlet 133 is disposed on the bottom plate in the cockpit space 12a and can providing cool air to the bottom of the back seat 122, which is conducive to the heat dissipation efficiency of the in-vehicle computer 14 (if disposed under the back seat 122). Furthermore, in actual use, if the weather is hot outside the vehicle 1, even when the air condition of the vehicle 1 is not turned on, the air temperature in the cockpit space 12a is still lower than other place inside the vehicle cage 12 in principle (e.g. the rear trunk 12b), so that the fan 146 still can draw relatively lower temperature air through the communication of the vent opening 142b with the cockpit space 12a, which is conducive to the heat dissipation.

In an embodiment according to the invention, the technology of the present invention can be applied to in-vehicle devices, such as self-driving cars, electric cars, semi-autonomous cars, and so on.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An in-vehicle computer, comprising:
a computer casing, having a casing accommodating space and a vent opening communicating with the casing accommodating space;
a filtering structure, detachably disposed at the vent opening;
an electronic component, disposed in the casing accommodating space; and
a fan, disposed in the casing accommodating space and spaced from the vent opening, the fan having a suction port and an exhaust port, the suction port being toward the vent opening, the fan generating an airflow for dissipating heat from the electronic component.

2. The in-vehicle computer according to claim 1, wherein the filtering structure comprises a bottom bracket, a replaceable filtering material, and an upper cover, the upper cover and the bottom bracket are engaged with each other to form a filter accommodating space, and the replaceable filtering material is accommodated in the filter accommodating space.

3. The in-vehicle computer according to claim 2, wherein the upper cover is detachably connected to the computer casing and covers the vent opening.

4. The in-vehicle computer according to claim 1, wherein the computer casing comprises a main casing and a fan cage, the main casing forms the casing accommodating space and the vent opening, the fan cage is disposed in the casing accommodating space corresponding to the vent opening, the fan cage has a top opening, the top opening is aligned with the vent opening, the fan is disposed on the fan cage, and the suction port is toward the top opening.

5. The in-vehicle computer according to claim 4, wherein the fan cage has a side through hole, and the exhaust port is connected to the side through hole.

6. The in-vehicle computer according to claim 1, further comprising a tubular structure, disposed in the casing accommodating space, wherein an end of the tubular structure is close to the suction port, and another end of the tubular structure is close to the filtering structure.

7. The in-vehicle computer according to claim 1, wherein the exhaust port is toward the electronic component.

8. A vehicle, comprising:
a vehicle cage, having a cockpit space; and
an in-vehicle computer, disposed in the vehicle cage and comprising:
a computer casing, having a casing accommodating space and a vent opening communicating with the casing accommodating space, the casing accommodating space communicating with the cockpit space through the vent opening;
a filtering structure, detachably disposed at the vent opening;
an electronic component, disposed in the casing accommodating space; and
a fan, disposed in the casing accommodating space and spaced from the vent opening, the fan having a suction port and an exhaust port, the suction port being toward the vent opening, the fan generating an airflow for dissipating heat from the electronic component.

9. The vehicle according to claim 8, wherein the vehicle cage comprises a back seat, and the in-vehicle computer is disposed behind the back seat.

10. The vehicle according to claim 9, wherein the vehicle cage comprises a speaker mesh cover, exposed from the cockpit space, and the speaker mesh cover covers the vent opening.

11. The vehicle according to claim 8, wherein the filtering structure comprises a bottom bracket, a replaceable filtering material, and an upper cover, the upper cover and the bottom bracket are engaged with each other to form a filter accommodating space, and the replaceable filtering material is accommodated in the filter accommodating space.

12. The vehicle according to claim 11, wherein the upper cover is detachably connected to the computer casing and covers the vent opening.

13. The vehicle according to claim 8, wherein the computer casing comprises a main casing and a fan cage, the main casing forms the casing accommodating space and the vent opening, the fan cage is disposed in the casing accommodating space corresponding to the vent opening, the fan cage has a top opening, the top opening is aligned with the vent opening, the fan is disposed on the fan cage, and the suction port is toward the top opening.

14. The vehicle according to claim 13, wherein the fan cage has a side through hole, and the exhaust port is connected to the side through hole.

15. The vehicle according to claim 8, wherein the in-vehicle computer further comprises a tubular structure, disposed in the casing accommodating space, an end of the tubular structure is close to the suction port, and another end of the tubular structure is close to the filtering structure.

16. The vehicle according to claim 8, wherein the exhaust port is toward the electronic component.
